(19) United States
(12) Patent Application Publication
(10) Pub. No.: US 2022/0032501 A1
(43) Pub. Date: Feb. 3, 2022

(54) METHOD FOR MANUFACTURING THREE-DIMENSIONAL FIRED BODY

(71) Applicant: NGK INSULATORS, LTD., Nagoya-City (JP)

(72) Inventors: Yasuho AOKI, Nagoya-City (JP); Masashi ONO, Nagoya-City (JP)

(73) Assignee: NGK INSULATORS, LTD., Nagoya-City (JP)

(21) Appl. No.: 17/451,204

(22) Filed: Oct. 18, 2021

Related U.S. Application Data
(63) Continuation of application No. PCT/JP2019/017718, filed on Apr. 25, 2019.

(51) Int. Cl. B28B 7/34; B33Y 80/00; B28B 11/24; B28B 1/14

(52) U.S. Cl. CPC B28B 7/346; B28B 1/14; B28B 11/243; B33Y 80/00

(57) ABSTRACT

A method for manufacturing a three-dimensional fired body includes (a) a step of producing a shaping mold using an organic material, the shaping mold having a shaping space which has the same shape as a shaped body having a hollow portion that opens to an outer surface thereof, in which a core corresponding to the hollow portion is integrated with the shaping mold; (b) a step of producing the shaped body in the shaping mold by pouring a ceramic slurry into the shaping space and solidifying the ceramic slurry; (c) a step of drying and then degreasing the shaped body, in which the shaping mold is eliminated in any one of the following stages: before drying, during drying, after drying and before degreasing, during degreasing, and after degreasing of the shaped body; and (d) a step of firing the shaped body to obtain a three-dimensional fired body.

### BACKGROUND OF THE INVENTION

### 1. Field of the Invention

The present invention relates to a method for manufacturing a three-dimensional fired body.

### 2. DESCRIPTION OF THE RELATED ART

As the method for manufacturing a three-dimensional fired body, for example, manufacturing methods described in Patent Literature 1 and Patent Literature 2 are known. Patent Literature 1 describes a method for manufacturing a ceramic tube. Specifically, first, a ceramic raw material powder is formed into a tube shape by isostatic pressing, using an inner mold (core) made of an organic thermoplastic material through which a core rod is passed and an outer mold (shaping mold) made of rubber. Next, the resulting shaped body is released from the outer mold, and the core rod is pulled out from the shaped body. Subsequently, the inner mold is melted by heating and made to flow out and removed from the inside of the shaped body, and the shaped article is fired to obtain a ceramic tube. Patent Literature 2 describes a method for manufacturing a shaped body having an undercut. Specifically, first, a core is arranged in a shaping mold. At this time, a placing piece made of a thermoplastic material is placed on a portion of the core which provides an undercut-forming mold surface. In the shaping mold, an outer peripheral portion of the core is filled with a ceramic material and shaping is performed. Then, a shaped body is released from the shaping mold. Subsequently, a metal pin is pulled out from the core, and by heating, the placing piece is made to flow out and removed, thus obtaining a shaped body having an undercut on an inner surface thereof.

### CITATION LIST

### Patent Literature

PTL 1: JP S46-61514 A

PTL 2: JP S60-154007 A

### SUMMARY OF THE INVENTION

However, in the manufacturing methods according to Patent Literature 1 and Patent Literature 2, an operation is required in which a core that is separate from a shaping mold is installed in the shaping mold, and at this time, it is also required to control the position of the core. Furthermore, in order to release a shaped body from the shaping mold, it is also required to apply a mold releasing agent to the shaping mold and to clean the shaping mold.

The present invention has been made to solve the problems described above. A major object thereof is to easily and accurately manufacture a three-dimensional fired body.

A method for manufacturing a three-dimensional fired body according to the present invention includes: (a) a step of producing a shaping mold using an organic material, the shaping mold having a shaping space which has the same shape as a shaped body having a hollow portion that opens to an outer surface thereof, in which a core corresponding to the hollow portion is integrated with the shaping mold; (b) a step of producing the shaped body in the shaping mold by pouring a ceramic slurry into the shaping space of the shaping mold and solidifying the ceramic slurry; (c) a step of drying and then degreasing the shaped body, in which the shaping mold is eliminated in any one of the following stages: before drying, during drying, after drying and before degreasing, during degreasing, and after degreasing of the shaped body; and (d) a step of firing the shaped body to obtain a three-dimensional fired body.

In the method for manufacturing a three-dimensional fired body, by using a shaping mold with which a core corresponding to a hollow portion of a shaped body is integrated, a ceramic slurry is solidified to produce the shaped body. Therefore, it is not required to install the core in the shaping mold or to control the position of the core. Furthermore, the shaping mold is eliminated in any one of the following stages: before drying, during drying, after drying and before degreasing, during degreasing, and after degreasing of the shaped body. Therefore, it is also not required to apply a mold releasing agent to the shaping mold or to clean the shaping mold. Accordingly, it is possible to easily and accurately manufacture a three-dimensional fired body compared with the known techniques.

Furthermore, the method of eliminating the shaping mold is not particularly limited. For example, the shaping mold may be eliminated by melting and removing the shaping mold, or the shaping mold may be eliminated by chemical decomposition (e.g., pyrolysis) of the shaping mold.

In the method for manufacturing a three-dimensional fired body according to the present invention, in the step (c), the shaping mold may be eliminated by melting and removing the shaping mold. In the case where the shaping mold is eliminated by burning the shaping mold, there is a concern that the components contained in the shaped body may also be burned, resulting in occurrence of unevenness on the surface of the shaped body. However, here, since the shaping mold is melted and removed, there is no such a concern. At this time, the shaping mold may be eliminated by melting and removing the shaping mold under the conditions in which components of the shaped body are not melted and removed. In this way, it is possible to prevent the shaped body from being deformed at the time of melting and removing the shaping mold.

In the method for manufacturing a three-dimensional fired body according to the present invention, in the step (a), the shaping mold may be produced using a 3D printer, and in the 3D printer, as a model material, a material that, after being hardened, is insoluble in a predetermined cleaning solution and components contained in the ceramic slurry may be used, and as a support material, a material that, after being hardened, is soluble in the predetermined cleaning solution may be used. In the present description, the term “insoluble” includes, in addition to a case of being completely insoluble, a case of being soluble to such a degree that a desired shape can be maintained. In this way, a shaping mold with which a core is integrated can be relatively easily produced, and there is no concern that the shaping mold will be dissolved out by the components contained in the ceramic slurry to such a degree that the shape cannot be maintained.

In the method for manufacturing a three-dimensional fired body according to the present invention, in the step (b), a slurry containing a ceramic powder and a gelling agent may be used as the ceramic slurry, and after the ceramic slurry is poured into the shaping mold, by subjecting the gelling agent to a chemical reaction to form the ceramic slurry into a gel, the shaped body may be produced in the shaping mold. In this way, since the shaping space of the shaping mold with which the core is integrated is completely filled with the ceramic slurry, the shaped body accurately corresponds to the shape of the shaping space.

In the method for manufacturing a three-dimensional fired body according to the present invention, the three-dimensional fired body may be a plug which is fitted into a plug installation hole provided on a surface opposite to a wafer placement surface of an electrostatic chuck, the plug having a gas passage that passes through the electrostatic chuck in the thickness direction thereof in a winding manner, in which the plug may be used to supply a gas through the gas passage to a thin hole that is provided on the bottom of the plug installation hole so as to pass through the electrostatic chuck in the thickness direction thereof. Such a plug is, for example, a component that is similar to a plasma arrestor for an electrostatic chuck described in U.S. Patent Application Publication No. 2017/0243726 (US2017/0243726). In this U.S. Patent Application, since a precursor (shaped body) of the arrestor is produced by a 3D printer, it becomes difficult to discharge a shaping material from a gas passage. In contrast, in the manufacturing method according to the present invention, a ceramic slurry is poured into a shaping mold which has a shaping space having the same shape as a shaped body of a plug, in which a core is integrated with the shaping mold, and then, the ceramic slurry is solidified to produce a shaped body. Therefore, a gas passage can be easily formed.

### BRIEF DESCRIPTION OF THE DRAWINGS

FIG. 1 is a longitudinal sectional view of a component for semiconductor manufacturing equipment 10.

FIG. 2 is a flowchart showing steps for manufacturing a plug 30.

FIG. 3 is a perspective view of a shaped body 50 for producing a plug 30.

FIG. 4 is a perspective view of a shaping mold 70 for producing the shaped body 50.

FIG. 5 is a sectional view showing a shaping mold 70 cut in half in the longitudinal direction.

FIG. 6 is a longitudinal sectional view of a ceramic tube 100.

FIG. 7 is a longitudinal sectional view of a ceramic tube 110.

FIG. 8 is a longitudinal sectional view of a ceramic member 120.

FIG. 9 is a partial longitudinal sectional view of another example of a component for semiconductor manufacturing equipment.

### DETAILED DESCRIPTION OF THE INVENTION

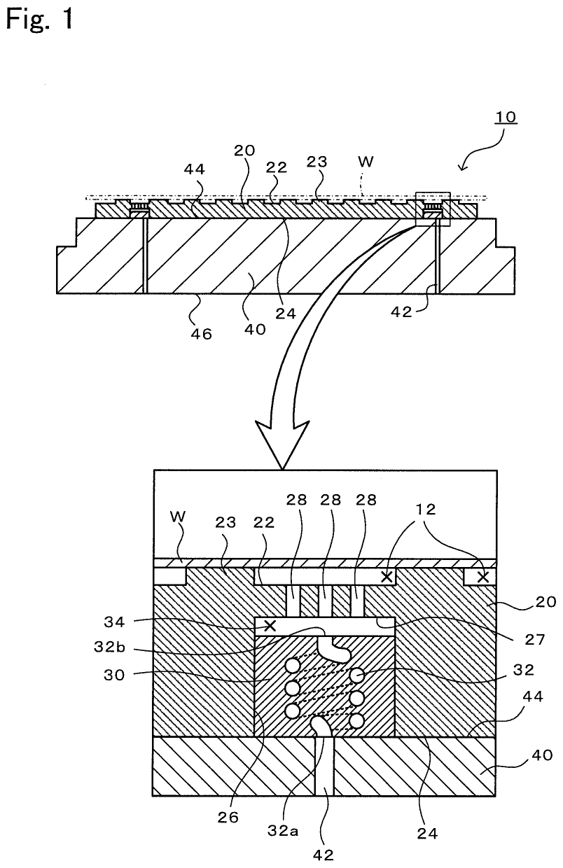

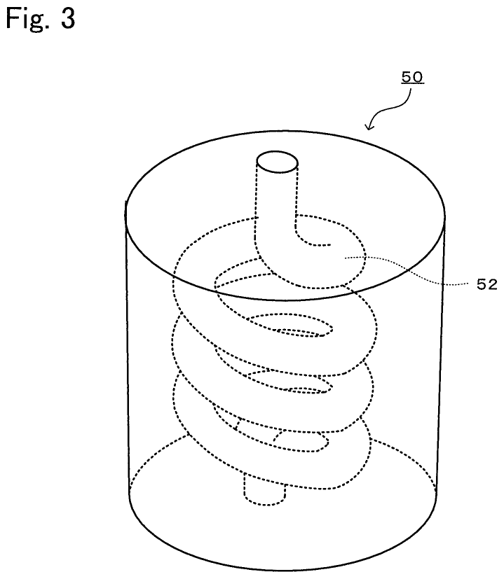

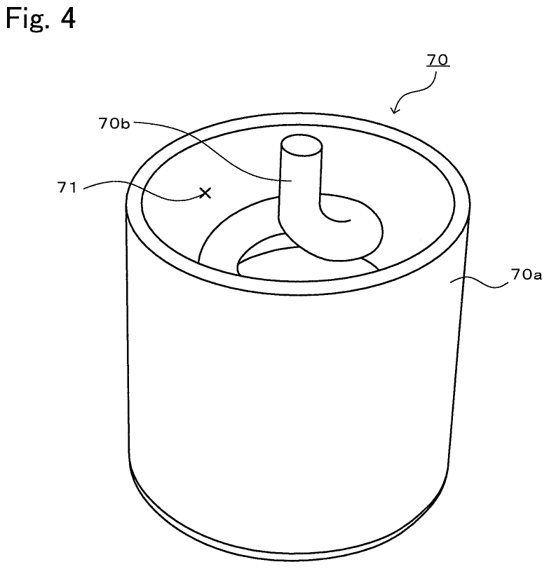

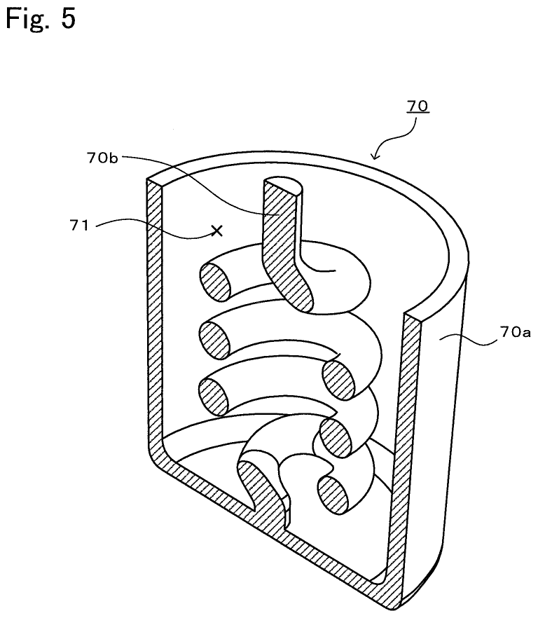

A preferred embodiment of the present invention will be described below with reference to the drawings. FIG. 1 is a longitudinal sectional view (with a partially enlarged view) of a component for semiconductor manufacturing equipment 10, FIG. 3 is a perspective view of a shaped body 50 for producing a plug 30, FIG. 4 is a perspective view of a shaping mold 70 for producing the shaped body 50, and FIG. 5 is a sectional view showing the shaping mold 70 cut in half in the longitudinal direction.

The component for semiconductor manufacturing equipment 10 is a component in which an electrostatic chuck 20 having a wafer placement surface 22 is disposed on a cooling device 40. A plurality of small protuberances 23 are provided by embossing on the wafer placement surface 22. A wafer W to be subjected to plasma treatment is mounted on the small protuberances 23.

The cooling device 40 is a disc-shaped member made of metal such as aluminum and has a gas feed hole 42. In the cooling device 40, the gas feed hole 42 communicates between a bonding surface 44 bonded to the electrostatic chuck 20 and a lower surface 46 opposite to the bonding surface 44. The bonding surface 44 of the cooling device 40 is bonded through a bonding sheet (not shown) to a lower surface 24 of the electrostatic chuck 20.

The electrostatic chuck 20 is a dense disc-shaped member made of ceramic such as alumina or aluminum nitride and has a plug installation hole 26 and a plurality of thin holes 28 which communicate with the plug installation hole 26. The plug installation hole 26 is formed from a position facing the gas feed hole 42 of the lower surface 24 of the electrostatic chuck 20 toward the wafer placement surface 22. Accordingly, the plug installation hole 26 communicates with the gas feed hole 42. Furthermore, the internal space of the plug installation hole 26 has a cylindrical shape. The thin holes 28 have a smaller diameter than that of the plug installation hole 26 and pass from a bottom surface 27 of the plug installation hole 26 to the wafer placement surface 22. The thin holes 28 open to a portion of the wafer placement surface 22 where small protuberances 23 are not formed. Furthermore, a plurality of (e.g., seven) thin holes 28 are provided on a plug installation hole 26. A dense plug 30 made of ceramic is fitted into the plug installation hole 26. The plug 30 is a cylindrical member and has a gas passage 32 that passes through the electrostatic chuck 20 in the thickness direction (upward/downward direction) thereof. The plug 30 is, for example, bonded with an adhesive to the side wall of the plug installation hole 26. The gas passage 32 is formed into a winding shape (here, a spiral shape) and extends from an opening 32a provided on the lower surface of the plug 30 to an opening 32b provided on the upper surface of the plug 30. The lower surface of the plug 30 is flush with the lower surface 24 of the electrostatic chuck 20. A gas reservoir space 34 is provided between the upper surface of the plug 30 and the bottom surface 27 of the plug installation hole 26.

Such a component for semiconductor manufacturing equipment 10 is installed in a chamber (not shown). A wafer W is mounted on the wafer placement surface 22. By introducing a raw material gas into the chamber and applying an RF voltage for forming plasma to the cooling device 40, plasma is generated to perform treatment on the wafer W. At this time, a backside gas, such as helium, is introduced into the gas feed hole 42 from a gas cylinder (not shown). The backside gas passes through the gas feed hole 42, the gas passage 32 of the plug 30, the gas reservoir space 34, and the thin holes 28 and is supplied to a space 12 on the back surface side of the wafer W. When generating plasma as described above, supposing that the gas passage 32 has a straight shape, discharging may occur between the wafer W and the cooling device 40 in some cases. However, in the embodiment, since the gas passage 32 is spiral, it is possible to prevent discharging between the wafer W and the cooling device 40.

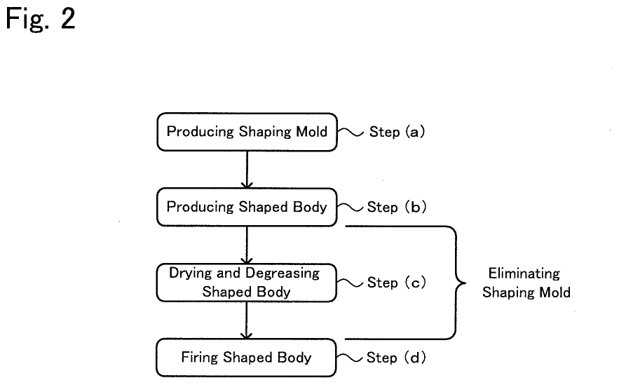

Next, a manufacturing example of a plug 30 will be described. The manufacturing example includes, as shown in the manufacturing flow of FIG. 2, (a) a step of producing a shaping mold 70, (b) a step of producing a shaped body 50, (c) a step of drying and degreasing the shaped body 50, and (d) a step of firing the shaped body 50. A shaped body 50 shown in FIG. 3 after firing becomes a plug 30, and the size of the shaped body 50 is determined on the basis of the size of the plug 30, in consideration of densification during firing. The shaped body 50 has a spiral hollow portion 52 which after firing becomes a gas passage 32. The hollow portion 52 opens to the upper surface and lower surface of the shaped body 50.

Step (a)

In step (a), a shaping mold 70 is produced. As shown in FIGS. 4 and 5, the shaping mold 70 includes a bottomed cylindrical main body 70a and a spiral core 70b corresponding to a hollow portion 52 of a shaped body 50. The shaping mold 70 has a shaping space 71 having the same shape as the shaped body 50. The shaping space 71 corresponds to a space obtained by excluding the core 70b from the cylindrical space inside the main body 70a. The lower end of the core 70b is integrated with the bottom surface of the shaping mold 70. The upper end of the core 70b is a free end. The shaping mold 70 is produced using a known 3D printer. A 3D printer forms a shaped body 50 by repeating a series of operations of discharging a fluid before hardened from a head toward a stage to form layers before hardened, and hardening the layers before hardened. The 3D printer includes, as the fluid before hardened, a model material which is a material constituting a portion of the shaping mold 70 that is finally required and a support material which is a material constituting a portion of the shaping mold 70 corresponding to a base for supporting the model material and is finally removed. Here, as the model material, a material (e.g., wax such as paraffin wax) that, after being hardened, is insoluble in a predetermined cleaning solution (water, an organic solvent, an acid, an alkali solution, or the like) and components contained in the ceramic slurry which will be described later is used. As the support material, a material (e.g., hydroxylated wax) that, after being hardened, is soluble in the predetermined cleaning solution is used. Examples of the predetermined cleaning solution include isopropyl alcohol. The 3D printer forms a structure using slice data in which the shaping mold 70 is horizontally sliced in layers with predetermined spacing from the bottom to the top. The slice data is obtained by processing CAD data. Some slice data includes a mixture of the model material and the support material, and some slice data includes the model material only. The structure formed by the 3D printer is immersed in isopropyl alcohol to dissolve out the hardened support material, and thus, an object formed of only the hardened model material, i.e., a shaping mold 70, is obtained.

Step (b)

In step (b), a shaped body 50 is produced in the shaping mold 70. Here, the shaped body 50 is produced by mold cast forming. The mold cast forming is a method also referred to as gel cast forming, and the details thereof are disclosed, for example, in Japanese Patent No. 5458050, etc. In the mold cast forming, a ceramic slurry containing a ceramic powder, a solvent, a dispersant, and a gelling agent is poured into a shaping space 71 of the shaping mold 70, and by subjecting the gelling agent to a chemical reaction to form the ceramic slurry into a gel, the shaped body 50 is produced in the shaping mold 70. Although the solvent is not particularly limited as long as it dissolves the dispersant and the gelling agent, preferably, a solvent having two or more ester bonds, such as a polybasic acid ester (e.g., dimethyl glutarate) or a polyhydric alcohol acid ester (e.g., triacetin), is used. Although the dispersant is not particularly limited as long as it homogeneously disperses the ceramic powder in the solvent, preferably, a polycarboxylic acid-based copolymer, a polycarboxylate, or the like is used. As the gelling agent, for example, a gelling agent containing an isocyanate, a polyol, and a catalyst may be used. The isocyanate is not particularly limited as long as it has an isocyanate group as a functional group. Examples thereof include tolylene diisocyanate (TDI), diphenylmethane diisocyanate (MDI), and modified products thereof. The polyol is not particularly limited as long as it is a material having two or more hydroxyl groups capable of reacting with an isocyanate group. Examples thereof include ethylene glycol (EG), polyethylene glycol (PEG), propylene glycol (PG), and polypropylene glycol (PPG). The catalyst is not particularly limited as long as it is a material which accelerates a urethane reaction between an isocyanate and a polyol. Examples thereof include triethylenediamine, hexanediamine, and 6-dimethylamino-1-hexanol. Here, the gelling reaction is a reaction in which a urethane reaction takes place between an isocyanate and a polyol to form a urethane resin (polyurethane). The ceramic slurry is formed into a gel by the reaction of the gelling agent, and the urethane resin functions as an organic binder.

Step (c)

In step (c), the shaped body 50 is dried and then degreased. The shaped body 50 is dried in order to evaporate the solvent contained in the shaped body 50. The drying temperature may be appropriately set depending on the solvent used, and for example, may be set to be 30 to 200° C. However, the drying temperature is carefully set so that cracks do not occur in the shaped body 50 during drying. Furthermore, the atmosphere may be any of the air atmosphere, an inert atmosphere, and a vacuum atmosphere. The shaped body 50 after drying is degreased in order to decompose and remove solid organic substances, such as the dispersant and the catalyst, contained in the shaped body 50. The degreasing temperature may be appropriately set depending on the types of the organic substances contained, and for example, may be set to be 200 to 600° C. Furthermore, the atmosphere may be any of the air atmosphere, an inert atmosphere, a vacuum atmosphere, and a hydrogen atmosphere. The shaped body 50 after degreasing may be calcined. The calcination temperature is not particularly limited, and, for example, may be set to be 600 to 1,200° C. Furthermore, the atmosphere may be any of the air atmosphere, an inert atmosphere, and a vacuum atmosphere.

In step (c), the shaping mold 70 is eliminated in any one of the following stages: before drying, during drying, after drying and before degreasing, during degreasing, and after degreasing of the shaped body 50. For example, in the case where, as the material for the shaping mold 70, a material having a melting point that is equal to or lower than the drying temperature of the shaped body 50 (when the melting point is defined in a temperature range, the upper-limit temperature thereof, the same applies to below) is used, the shaping mold 70 may be melted and removed, before drying of the shaped body 50, by heating the shaped body 50 placed in the shaping mold 70 to a temperature that is equal to or higher than the melting point and lower than the drying temperature, or the shaping mold 70 may be melted and removed at the drying temperature during drying of the shaped body 50. For example, in the case where wax that melts at 70° C. is used as the material for the shaping mold 70, before drying of the shaped body 50, by heating the shaping mold 70 to 70° C., the shaping mold 70 can be melted and removed. Alternatively, in the case where, as the material for the shaping mold 70, a material having a melting point that is higher than the drying temperature and equal to or lower than the degreasing temperature of the shaped body 50 is used, the shaping mold 70 may be melted and removed, after drying and before degreasing of the shaped body 50, by heating the shaped body 50 placed in the shaping mold 70 to a temperature that is equal to or higher than the melting point and lower than the degreasing temperature, or the shaping mold 70 may be melted and removed at the degreasing temperature during degreasing of the shaped body 50. As the components of the shaped body 50, preferably, materials that are not melted and removed at the temperature at which the shaping mold 70 is melted and removed are used. In this way, it is possible to prevent the shaped body 50 from being deformed at the time of melting and removing the shaping mold 70. In stead of melting and removing the shaping mold 70, the shaping mold 70 may be eliminated by burning. For example, in the case where as the material for the shaping mold 70, a material that does not melt at the drying temperature and the degreasing temperature is used, the shaping mold 70 may be eliminated by burning after degreasing and during calcining or firing of the shaped body 50.

Step (d)

In step (d), by firing the shaped body 50, a plug 30 is produced. The firing temperature (highest temperature) may be appropriately set in consideration of the temperature at which the ceramic powder contained in the shaped body 50 is sintered. Furthermore, the firing atmosphere may be selected from the air atmosphere, an inert gas atmosphere, a vacuum atmosphere, a hydrogen atmosphere, and the like.

In the method for manufacturing the plug 30 according to the embodiment described above, by using the shaping mold 70 in which the core 70b corresponding to the hollow portion 52 of the shaped body 50 is integrated with the bottomed cylindrical main body 70a, a ceramic slurry is solidified to produce the shaped body 50. Therefore, it is not required to install the core 70b in the main body 70a of the shaping mold 70 or to control the position of the core 70b. Furthermore, the shaping mold 70 is eliminated in any one of the following stages: before drying, during drying, after drying and before degreasing, during degreasing, and after degreasing of the shaped body 50. Therefore, it is also not required to apply a mold releasing agent to the shaping mold 70 or to clean the shaping mold 70. Accordingly, it is possible to easily and accurately manufacture a plug 30 compared with the known techniques.

Furthermore, in step (b), a slurry containing a ceramic powder and a gelling agent is used as the ceramic slurry, and after the ceramic slurry is poured into the shaping space 71 of the shaping mold 70, by subjecting the gelling agent to a chemical reaction to form the ceramic slurry into a gel, the shaped body 50 is produced in the shaping mold 70. In this way, since the shaping space 71 of the shaping mold 70 in which the core 70b is integrated with the main body 70a is completely filled with the ceramic slurry, the shaped body 50 accurately corresponds to the shape of the shaping space 71.

Furthermore, in step (c), in the case where the shaping mold 70 is eliminate by burning, there is a concern that the components contained in the shaped body 50 may also be burned, resulting in occurrence of unevenness on the surface of the shaped body 50. When the shaping mold 70 is eliminated by melting and removing the shaping mold 70, there is no such a concern. At this time, when the shaping mold 70 is eliminated by melting and removing the shaping mold 70 under the conditions in which components of the shaped body 50 are not melted and removed, it is possible to prevent the shaped body 50 from being deformed at the time of melting and removing the shaping mold 70.

Furthermore, in step (a), the shaping mold 70 is produced using a 3D printer, and in the 3D printer, as a model material, a material that, after being hardened, is insoluble in a predetermined cleaning solution and components contained in the ceramic slurry is used, and as a support material, a material that, after being hardened, is soluble in the predetermined cleaning solution is used. Accordingly, a shaping mold 70 in which a core 70b is integrated with a main body 70a can be relatively easily produced, and there is no concern that the shaping mold 70 will be dissolved out by the components contained in the ceramic slurry.

It is to be understood that the present invention is not limited to the embodiments described above, and various embodiments are possible within the technical scope of the present invention.

For example, in the embodiment described above, the shaping mold 70 is produced by a 3D printer. However, the present invention is not limited thereto. For example, the shaping mold 70 may be produced by injection molding, slip casting, machining, or the like. However, by using a 3D printer, the shaping mold 70 can be easily and accurately produced.

In the embodiment described above, the shaped body 50 is produced by mold cast forming. However, the present invention is not limited thereto. For example, a ceramic powder in a solid form may be directly subjected to shaping. However, by using mold cast forming, the shaped body 50 can be easily and accurately produced.

In the embodiment described above, in step (b), mold cast forming using a urethane reaction is described as an example. However, an epoxy curing reaction may be used. For example, a shaped body 50 may be produced by pouring a ceramic slurry, in which a ceramic powder, an epoxy resin, and a curing agent are dispersed and mixed, into a shaping mold 70, followed by heating the ceramic slurry while humidifying to cure the epoxy resin. In this case, as the shaping mold 70, a material that does not melt in an environment where the epoxy resin is cured is selected.

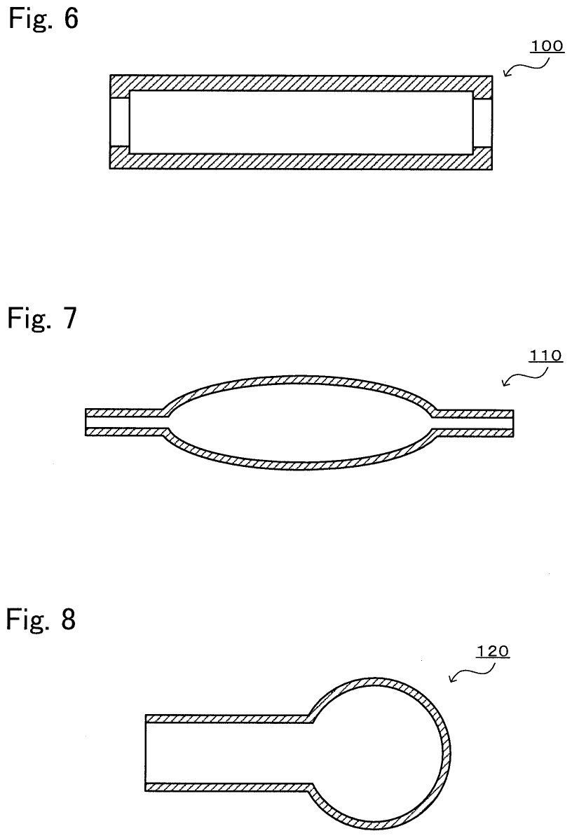

In the embodiment described above, a plug 30 is exemplified as a three-dimensional fired body. However, the three-dimensional fired body is not particularly limited to the plug 30. The present invention can be applied to any three-dimensional fired body having a hollow portion that opens to an outer surface thereof. For example, as the three-dimensional fired body, as shown in FIG. 6, a cylindrical ceramic tube 100 (refer to Patent Literature 1) may be employed. As shown in FIG. 7, a ceramic tube 110 having a shape in which straight tubes are provided at both ends of a hollow ellipsoid (refer to Patent Literature 1) may be employed. As shown in FIG. 8, a ceramic member 120 having a shape in which a straight tube is provided at an end of a hollow sphere (refer to Patent Literature 2) may be employed. Since all of these have a hollow portion that opens to the outer surface thereof, by using a shaping mold formed of an organic material with which a core corresponding to the hollow portion is integrated, the three-dimensional fired body can be manufactured in the same manner as that in the embodiment described above.

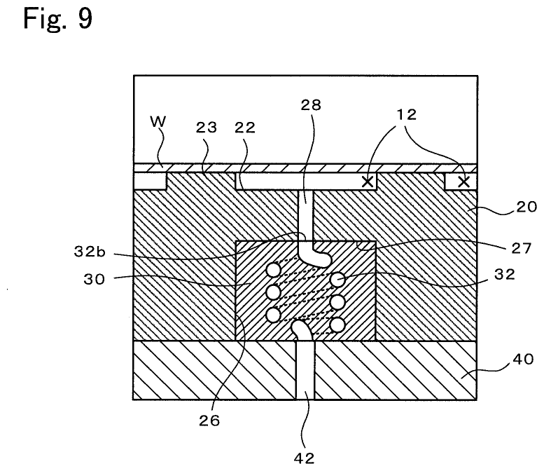

In the embodiment described above, as shown in FIG. 1, the gas reservoir space 34 is provided between the upper surface of the plug 30 and the bottom surface 27 of the plug installation hole 26, and a plurality of thin holes 28 are provided on a plug installation hole 26. Instead of this, for example, a structure shown in FIG. 9 may be employed. In FIG. 9, the upper surface of a plug 30 corresponds to the bottom surface 27 of a plug installation hole 26. Furthermore, one thin hole 28 is provided on a plug installation hole 26 and passes from the bottom surface 27 at a position corresponding to an opening 32b of a gas passage 32 to a portion of a wafer placement surface 22 where small protuberances 23 are not formed. In the case where the structure of FIG. 9 is employed, a backside gas, such as helium, is also introduced into a gas feed hole 42 from a gas cylinder (not shown). The backside gas can be supplied through the gas feed hole 42 of the cooling device 40, the gas passage 32 of the plug 30, and the thin hole 28 of the electrostatic chuck 20 to a space 12 on the back surface side of the wafer W.

What is claimed is:

1. A method for manufacturing a three-dimensional fired body comprising:
(a) a step of producing a shaping mold using an organic material, the shaping mold having a shaping space which has the same shape as a shaped body having a hollow portion that opens to an outer surface thereof, wherein a core corresponding to the hollow portion is integrated with the shaping mold;
(b) a step of producing the shaped body in the shaping mold by pouring a ceramic slurry into the shaping space of the shaping mold and solidifying the ceramic slurry;
(c) a step of drying and then degreasing the shaped body, wherein the shaping mold is eliminated in any one of the following stages: before drying, during drying, after drying and before degreasing, during degreasing, and after degreasing of the shaped body; and
(d) a step of firing the shaped body to obtain a three-dimensional fired body.

2. The method for manufacturing a three-dimensional fired body according to claim 1, wherein, in the step (c), the shaping mold is eliminated by melting and removing the shaping mold.

3. The method for manufacturing a three-dimensional fired body according to claim 2, wherein, in the step (c), the shaping mold is eliminated by melting and removing the shaping mold under the conditions in which components of the shaped body are not melted and removed.

4. The method for manufacturing a three-dimensional fired body according to claim 1, wherein, in the step (a), the shaping mold is produced using a 3D printer, and in the 3D printer, as a model material, a material that, after being hardened, is insoluble in a predetermined cleaning solution and components contained in the ceramic slurry is used, and as a support material, a material that, after being hardened, is soluble in the predetermined cleaning solution is used.

5. The method for manufacturing a three-dimensional fired body according to claim 1, wherein, in the step (b), a slurry containing a ceramic powder and a gelling agent is used as the ceramic slurry, and after the ceramic slurry is poured into the shaping mold, by subjecting the gelling agent to a chemical reaction to form the ceramic slurry into a gel, the shaped body is produced in the shaping mold.

6. The method for manufacturing a three-dimensional fired body according to claim 1, wherein the three-dimensional fired body is a plug which is fitted into a plug installation hole provided on a surface opposite to a wafer placement surface of an electrostatic chuck, the plug having a gas passage that passes through the electrostatic chuck in the thickness direction thereof in a winding manner;
wherein the plug is used to supply a gas through the gas passage to a thin hole that is provided on the bottom of the plug installation hole so as to pass through the electrostatic chuck in the thickness direction thereof.
